(19) United States
(12) Patent Application Publication
(10) Pub. No.: US 2024/0427238 A1
(43) Pub. Date: Dec. 26, 2024

(54) RESIST UNDERLAYER FILM-FORMING COMPOSITION

(71) Applicant: NISSAN CHEMICAL CORPORATION, Tokyo (JP)

(72) Inventors: Tetsuya KIMURA, Toyama-shi (JP); Hirokazu NISHIMAKI, Toyama-shi (JP)

(73) Assignee: NISSAN CHEMICAL CORPORATION, Tokyo (JP)

(21) Appl. No.: 18/698,428

(22) PCT Filed: Oct. 3, 2022
(86) PCT No.: PCT/JP2022/036991

§ 371 Date: Sep. 6, 2024

(30) Foreign Application Priority Data
Oct. 11, 2021 (JP) 2021-166987

(51) Int. Cl. G03F 7/027; G03F 7/004; G03F 7/025; H01L 21/311

(52) U.S. Cl. CPC G03F 7/027; G03F 7/0048; G03F 7/025; H01L 21/31127; H01L 21/31144

(57) ABSTRACT

A resist underlayer film-forming composition improves an ability to fill patterns during baking by improving heat-reflowability of a polymer; a resist underlayer film being a baked product of a coating film formed from the resist underlayer film-forming composition; and a method for producing a semiconductor device includes a step of forming the resist underlayer film. The resist underlayer film-forming composition includes a compound of the following formula (A) or (B) and a solvent.

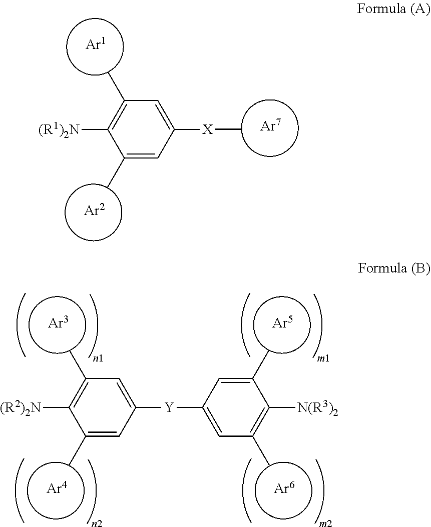

### TECHNICAL FIELD

The present invention relates to a resist underlayer film-forming composition for forming a flattened film on a substrate having a step, and a method for producing a flattened laminated substrate using the resist underlayer film.

### BACKGROUND ART

Conventionally, in production of semiconductor devices, fine processing by lithography has been performed using a photoresist composition. The fine processing is a processing method in which a thin film of a photoresist composition is formed on a substrate to be processed such as a silicon wafer, active light such as ultraviolet light is emitted onto the thin film through a mask pattern in which a semiconductor device pattern is drawn, developing is performed, and the substrate to be processed such as a silicon wafer is etched using the obtained photoresist pattern as a protective film. Incidentally, in recent years, as semiconductor devices have become highly integrated, the wavelength of active light used has been shortened from KrF excimer laser (248 nm) to ArF excimer laser (193 nm). Accordingly, the influence of diffused reflection and standing waves of active light from the substrate has become a major problem, and a method of providing an anti-reflective coating between a photoresist and a substrate to be processed has become widely applied. In addition, for finer processing, a lithography technology using extreme ultraviolet rays (EUV, 13.5 nm) or an electron beam (EB) as active light is also being developed. In the EUV lithography and EB lithography, generally, a specific anti-reflective coating is not required because diffused reflection or standing waves from the substrate do not occur, but the resist underlayer film has begun to be widely studied as an auxiliary coating in order to improve the resolution and adhesion of the resist pattern.

Incidentally, when the depth of focus decreases as the exposure wavelength becomes shorter, it is important to improve the flatness of the film formed on the substrate in order to form a desired resist pattern with high accuracy. That is, in order to produce semiconductor devices with fine design rules, a resist underlayer film with which the substrate can be coated flatly without any steps is essential.

For example, a resist underlayer film-forming composition containing a crosslinking compound having a C₂₋₁₀ alkoxymethyl group or a C₁₋₁₀ alkyl group has been disclosed (refer to Patent Document 1). It has been shown that an embedding property is favorable when a substrate having a hole pattern is applied using the composition.

In addition, a resist underlayer film-forming composition containing a novolac resin using phenyl naphthylamine has been disclosed (refer to Patent Document 2).

In addition, a resist underlayer film-forming composition containing a polymer obtained by reacting a novolac resin using phenyl naphthylamine with t-butoxystyrene has been disclosed (refer to Patent Document 3).

### PRIOR ART DOCUMENTS

### Patent Documents

Patent Document 1: WO2014/208542 A1
Patent Document 2: WO2013/047516 A1
Patent Document 3: WO2015/151803 A1

### SUMMARY OF THE INVENTION

### Problem to be Solved by the Invention

In the resist underlayer film-forming composition, in order to prevent mixing when photoresist compositions or different resist underlayer films are laminated, the coating film is thermally cured by introducing a self-crosslinking part into a polymer resin which is a main component or by appropriately adding a crosslinking agent, a crosslinking catalyst or the like, and baking at a high temperature. Accordingly, it is possible to laminate photoresist compositions or different resist underlayer films without mixing. However, since such a thermosetting resist underlayer film-forming composition contains a polymer having a thermal crosslink-forming functional group such as a hydroxyl group, a crosslinking agent, and an acid catalyst (acid generating agent), when the composition is filled into a pattern (for example, a hole or a trench structure) formed on the substrate, the viscosity increases as the cross-linking reaction proceeds due to baking, an ability to fill patterns deteriorates, and thus the flatness after film formation tends to deteriorate.

An object of the present invention is to improve an ability to fill patterns during baking by improving heat-reflowability of a thermosetting resist underlayer film-forming composition and to improve the flatness of a resist underlayer film.

Therefore, a resist underlayer film-forming composition for forming a resist underlayer film that also has heat resistance is provided.

### Means for Solving the Problem

That is, the present invention relates to, as a first aspect, a resist underlayer film-forming composition comprising a compound of the following Formula (A) and/or Formula (B), and a solvent:

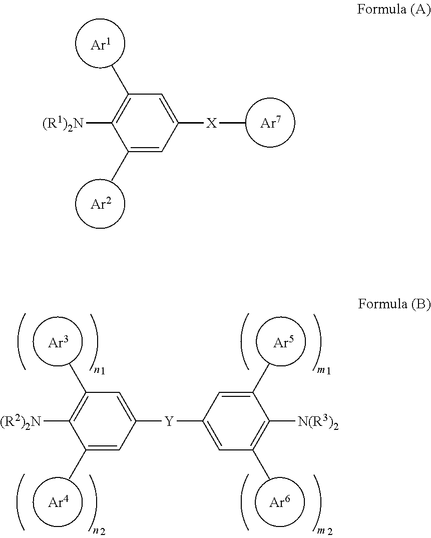

(in Formula (A), Ar¹ and Ar² are each independently a group consisting of one or more aromatic rings having a carbon atom number of 6 to 30 that is substitutable with Z¹, R¹ is a hydrogen atom, a C₁₋₁₀ alkyl group, a C₂₋₁₀ alkenyl group or a C₂₋₁₀ alkynyl group, X is a single bond or an oxygen atom, Ar⁷ is the same group as Ar¹ and Ar² when X is a single bond, and is a phenyl group or a naphthyl group when X is an oxygen atom,
in Formula (B), Ar³ to Ar⁶ have the same definition as Ar¹ and Ar², R² and R³ each have the same definition as R¹, Y is a single bond or a divalent group that is substitutable with Z², n1, n2, m1, and m2 are 0 or 1, and n1, n2, m1, m2 are not all 0 at the same time,
Z¹ is at least one selected from the group consisting of a halogen atom, a hydroxy group, a cyano group, a methylamino group, a methyl ether group, a cyclic alkyl group, a benzene group, a pyridine group, a C₁₋₁₀ alkyl group, a C₂₋₁₀ alkenyl group and a C₂₋₁₀ alkynyl group, and
Z² is at least one selected from the group consisting of a C₁₋₁₀ alkyl group and a C₁₋₁₀ fluoroalkyl group).

The present invention relates to, as a second aspect, the resist underlayer film-forming composition according to the first aspect, in which, in Formula (A) or Formula (B), Ar¹ to Ar⁶ are each independently a group consisting of one or more aromatic rings including a benzene ring.

The present invention relates to, as a third aspect, the resist underlayer film-forming composition according to the first aspect or second aspect, in which, in Formula (A), R¹ is a hydrogen atom or a C₂₋₁₀ alkynyl group.

The present invention relates to, as a fourth aspect, the resist underlayer film-forming composition according to any one of the first aspect to the third aspect, in which, in Formula (B), Ar³ to Ar⁶ are the same group.

The present invention relates to, as a fifth aspect, the resist underlayer film-forming composition according to any one of the first aspect to the fourth aspect, in which, in Formula (B), the divalent group is a group selected from the group consisting of a branched or linear alkylene group having a carbon atom number of 1 to 15, a phenylene group, a naphthalene group, an anthracenyl group, a sulfonyl group, a carbonyl group, an ether group, and a thioether group or a group of combinations thereof.

The present invention relates to, as a sixth aspect, the resist underlayer film-forming composition according to the fifth aspect, in which, in Formula (B), the divalent group is any of groups shown below:

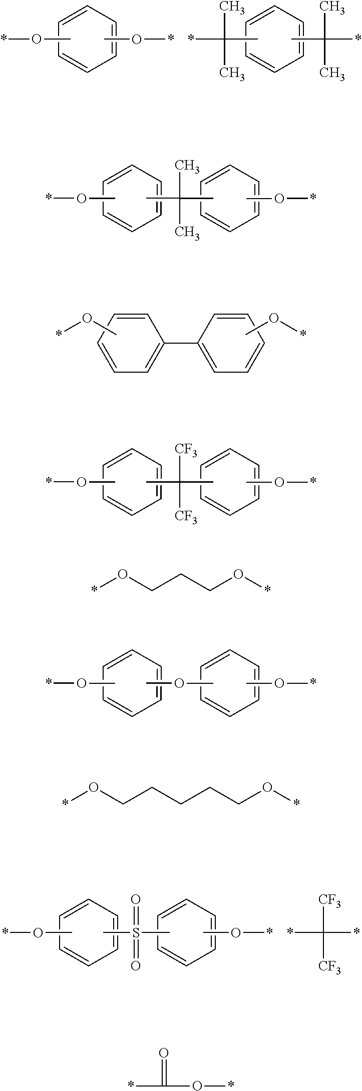

(* is a bond to an aromatic ring)

The present invention relates to, as a seventh aspect, the resist underlayer film-forming composition according to any one of the first aspect to the sixth aspect, in which, in Formula (B), R² and/or R³ are a hydrogen atom or a C₂₋₁₀ alkynyl group.

The present invention relates to, as an eighth aspect, the resist underlayer film-forming composition according to any one of the first aspect to the seventh aspect, further comprising a crosslinking agent.

The present invention relates to, as a ninth aspect, the resist underlayer film-forming composition according to any one of the first aspect to the eighth aspect, further comprising an acid and/or an acid generating agent.

The present invention relates to, as a tenth aspect, the resist underlayer film-forming composition according to any one of the first aspect to the ninth aspect, in which the solvent is a solvent having a boiling point of 160° C. or higher.

The present invention relates to, as an eleventh aspect, a resist underlayer film which is characterized by a baked product of a coating film formed from the resist underlayer film-forming composition according to any one of the first aspect to the tenth aspect.

The present invention relates to, as a twelfth aspect, a method for producing a semiconductor device, the method comprising:
a step of forming a resist underlayer film on a semiconductor substrate using the resist underlayer film-forming composition according to any one of the first aspect to the tenth aspect;
a step of forming a resist film on the resist underlayer film;
a step of forming a resist pattern by emitting light or an electron beam and development;
a step of etching the resist underlayer film with the resist pattern; and
a step of processing the semiconductor substrate with the resist underlayer film that is patterned.

### Effects of the Invention

The resist underlayer film-forming composition of the present invention not only has a high etching resistance and a favorable dry etching rate and optical constant, but the obtained resist underlayer film also has favorable coverage even for a so-called step substrate and a small difference in film thickness after embedding, forms a flat film, and achieves finer substrate processing.

Particularly, the resist underlayer film-forming composition of the present invention is effective in a lithography process in which at least two resist underlayer film layers are formed in order to reduce the thickness of a resist film, and the resist underlayer film is used as an etching mask.

### BRIEF DESCRIPTION OF THE DRAWINGS

FIG. 1 shows cross-sectional SEM images of the results obtained by performing a coating test on a step substrate using a resist underlayer film-forming composition prepared in Comparative Example 1. The left figure shows a dense pattern area, and the right figure shows an open area.

FIG. 2 shows cross-sectional SEM images of the results obtained by performing a coating test on a step substrate using a resist underlayer film-forming composition prepared in Example 2. The left figure shows a dense pattern area, and the right figure shows an open area.

### MODES FOR CARRYING OUT THE INVENTION

### [Resist Underlayer Film-Forming Composition]

A resist underlayer film-forming composition according to the present invention comprising a compound of the following Formula (A) and/or Formula (B) and a solvent:

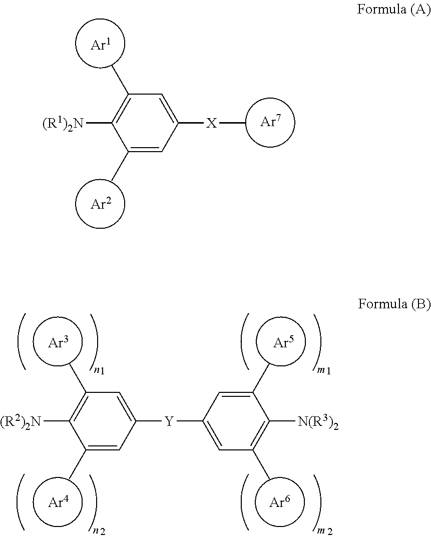

(in Formula (A), Ar¹ and Ar² are each independently a group consisting of one or more aromatic rings having a carbon atom number of 6 to 30 that is substitutable with Z¹, R¹ is a hydrogen atom, a C₁₋₁₀ alkyl group, a C₂₋₁₀ alkenyl group or a C₂₋₁₀ alkynyl group, X is a single bond or an oxygen atom, and Ar⁷ is the same group as Ar¹ and Ar² when X is a single bond, and is a phenyl group or a naphthyl group when X is an oxygen atom, in Formula (B), Ar³ to Ar⁶ have the same definition as Ar¹ and Ar², R² and R³ each have the same definition as R¹, Y is a single bond or a divalent group that is substitutable with Z², n1, n2, m1, and m2 are 0 or 1, and n1, n2, m1, m2 are not all 0 at the same time,
Z¹ is at least one selected from the group consisting of a halogen atom, a hydroxy group, a cyano group, a methylamino group, a methyl ether group, a cyclic alkyl group, a benzene group, a pyridine group, a C₁₋₁₀ alkyl group, a C₂₋₁₀ alkenyl group and a C₂₋₁₀ alkynyl group, and
Z² is at least one selected from the group consisting of a C₁₋₁₀ alkyl group and a C₁₋₁₀ fluoroalkyl group).

### [Compound of Formula (A)]

In Formula (A), Ar¹ and Ar² are each independently a group consisting of one or more aromatic rings having a carbon atom number of 6 to 30 that is substitutable with Z¹.

The substituent Z¹ is at least one selected from the group consisting of a halogen atom, a hydroxy group, a cyano group, a methylamino group, a methyl ether group, a cyclic alkyl group, a benzene group, a pyridine group, a C₁₋₁₀ alkyl group, a C₂₋₁₀ alkenyl group and a C₂₋₁₀ alkynyl group.

Specific examples of cyclic alkyl groups include cycloalkyl groups such as cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-I-methyl-cyclopropyl group, 2-ethyl-2-methyl-cyclopropyl group, and 2-ethyl-3-methyl-cyclopropyl group, and bicycloalkyl groups such as bicyclobutyl group, bicyclopentyl group, bicyclohexyl group, bicycloheptyl group, bicyclooctyl group, bicyclononyl group, and bicyclodecyl group, but the cyclic alkyl groups are not limited thereto.

For descriptions of the C₁₋₁₀ alkyl group, C₂₋₁₀ alkenyl group and C₂₋₁₀ alkynyl group, the description of the following R¹ will be referred to.

The group consisting of one or more aromatic rings having a carbon atom number of 6 to 30 that is substitutable with Z¹ may have a single aromatic ring which is substitutable with Z¹ or a group in which a plurality of benzene rings, naphthalene rings, and quinoline rings are bonded via a carbon atom, and among these, it is preferable to include a benzene ring. When there is a plurality of aromatic rings, the aromatic rings may be bonded to each other via a single bond.

Examples of such combinations of aromatic rings include those exemplified below, but the combinations are not limited thereto.

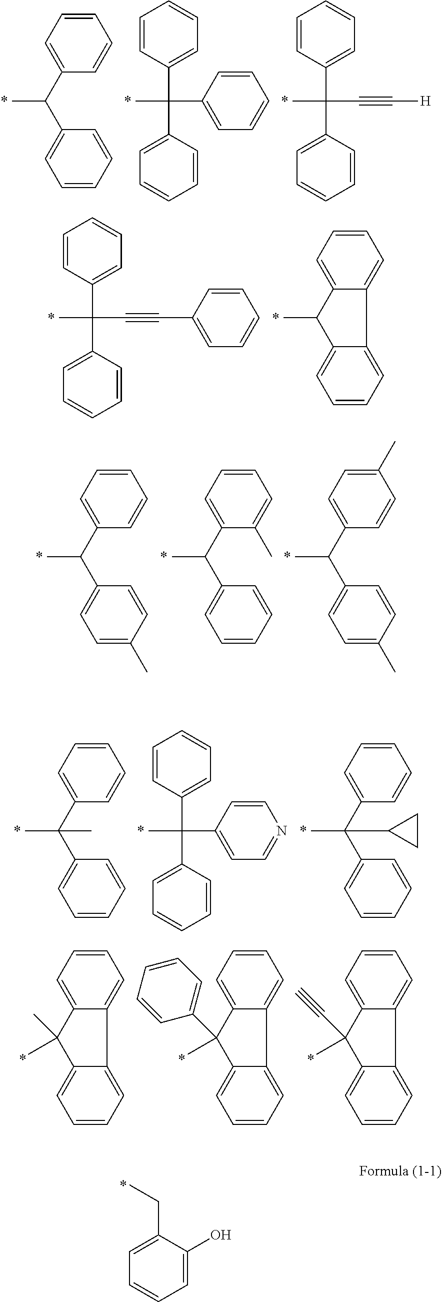

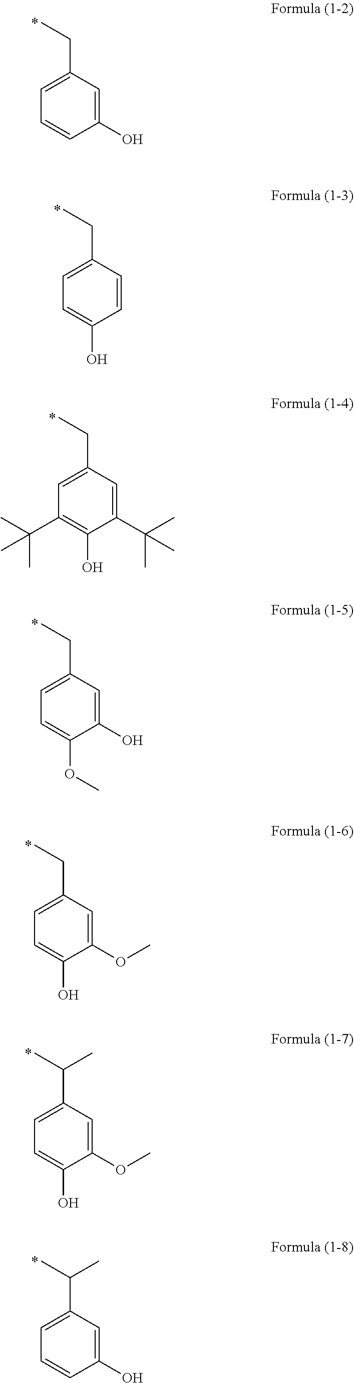

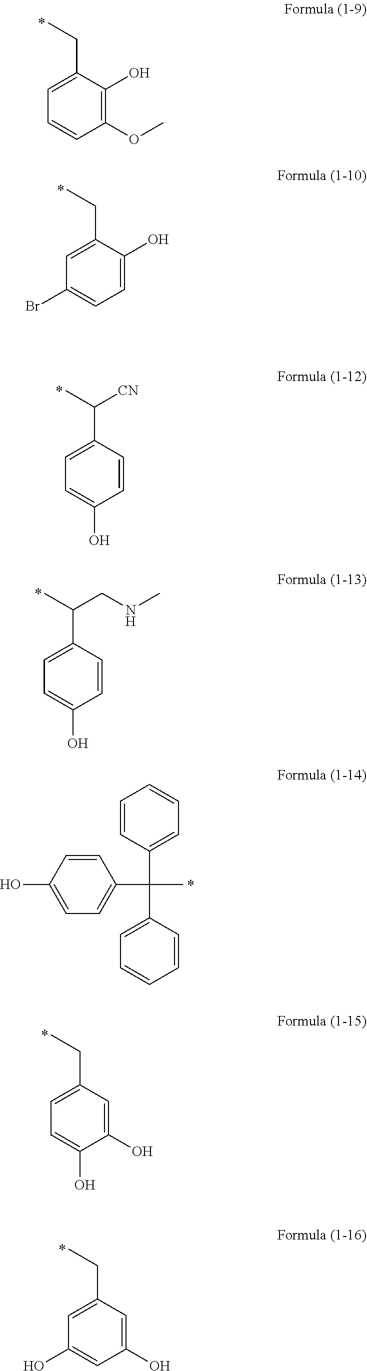

(* is a bond to a benzene ring)

In Formula (A), R¹ is a hydrogen atom, a C₁₋₁₀ alkyl group, a C₂₋₁₀ alkenyl group or a C₂₋₁₀ alkynyl group.

Examples of C₁₋₁₀ alkyl groups include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group and 2-ethyl-3-methyl-cyclopropyl group. These alkyl groups may be intervened by an oxygen atom, a carbonyl group, or a carboxyl group.

Among these, an alkyl group having a carbon atom number of 3 or less is preferable.

Examples of C₂₋₁₀ alkenyl groups include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group and 3-cyclohexenyl group.

These alkenyl groups may be intervened by an oxygen atom, a carbonyl group, or a carboxyl group. Among these, an alkenyl group having a carbon atom number of 5 or less is preferable.

Examples of C₂₋₁₀ alkynyl groups include ethynyl group, 1-propynyl group, 1-butynyl group, 1-pentynyl group, 1-hexynyl group, 1-methyl-3-pentynyl group, 1-methyl-3-hexynyl group, and 2-methyl-3-hexynyl group, and alkynyl groups such as those exemplified below may be exemplified.

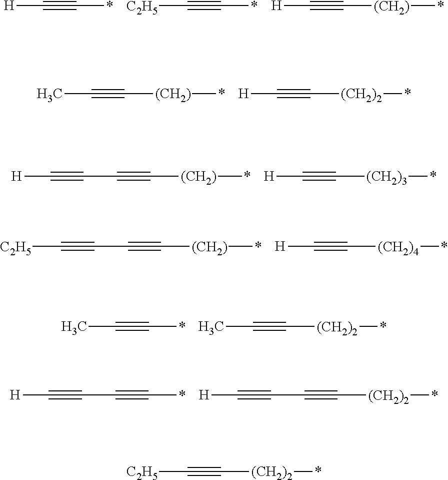

(when a C₂₋₁₀ alkynyl group is R¹, * is a bond to a nitrogen atom, and when a C₂₋₁₀ alkynyl group is Z¹, * is a bond to a combination of aromatic rings)

In Formula (A), R¹ is preferably a hydrogen atom or a C₂₋₁₀ alkynyl group.

In Formula (A), X is a single bond or an oxygen atom.

In Formula (A), Ar⁷ is the same group as Ar¹ and Ar² when X is a single bond, and is a phenyl group or a naphthyl group when X is an oxygen atom.

Examples of such compounds of Formula (A) include the following compounds.

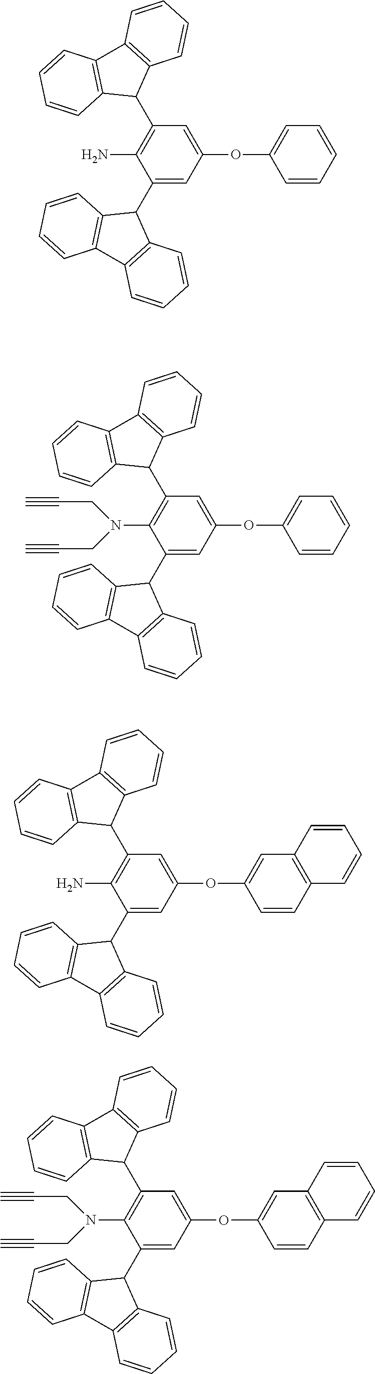

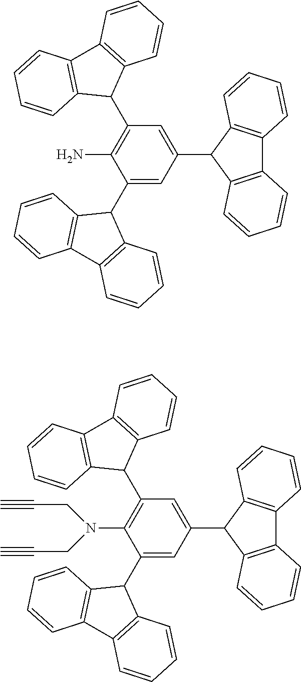 [SMILES: Nc1c(C2c3ccccc3-c3ccccc32)cc(C2c3ccccc3-c3ccccc32)cc1C1c2ccccc2-c2ccccc21 ; C#CCN(CC#C)c1c(C2c3ccccc3-c3ccccc32)cc(C2c3ccccc3-c3ccccc32)cc1C1c2ccccc2-c2ccccc21]

### [Compound of Formula (B)]

In Formula (B), Ar³ to Ar⁶ have the same definitions as Ar¹ and Ar² described above, and are each independently a group consisting of one or more aromatic rings having a carbon atom number of 6 to 30 that is substitutable with Z¹, and Ar³ to Ar⁶ are preferably the same group. In addition, Ar³ to Ar⁶ are each independently a group consisting of one or more aromatic rings having a carbon atom number of 6 to 30 and including a benzene ring that is substitutable with Z¹.

In Formula (B), R² and R³ each have the same definition as R described above. Here, R² and/or R³ are preferably a hydrogen atom or a C₂₋₁₀ alkynyl group. R² and R³ may be different groups, but they are preferably the same group.

In Formula (B), Y is a single bond or a divalent group that is substitutable with Z². Such a divalent group is a group selected from the group consisting of a branched or linear alkylene group having a carbon atom number of 1 to 15, a phenylene group, a naphthalene group, an anthracenyl group, a sulfonyl group, a carbonyl group, an oxygen atom (ether group) and a sulfur atom (thioether group) or a group of combinations thereof.

When Y is substituted with the substituent Z², one or more substituents Z² can be provided. The substituent Z² is at least one selected from the group consisting of a C₁₋₁₀ alkyl group and a C₁₋₁₀ fluoroalkyl group.

Examples of C₁₋₁₀ fluoroalkyl groups include perfluoromethyl group, perfluoroethyl group, perfluoropropyl group, and perfluorobutyl group.

Z² is preferably a methyl group or a perfluoromethyl group.

In Formula (B), n1, n2, m1, and m2 are 0 or 1, n1, n2, m1, m2 are not all 0 at the same time, and it is preferable that at least one of n1 and n2 be 1, and at least one of m1 and m2 be 1.

The aforementioned divalent groups may be used alone or two or more thereof may be used in combination.

Examples of such combinations include groups exemplified below, but the combinations are not limited thereto.

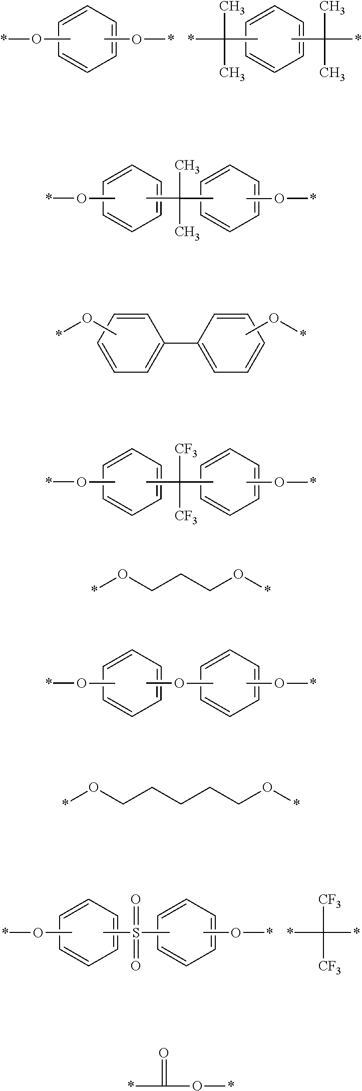

(* is a bond to an aromatic ring)

Examples of such compounds of Formula (B) include the following compounds.

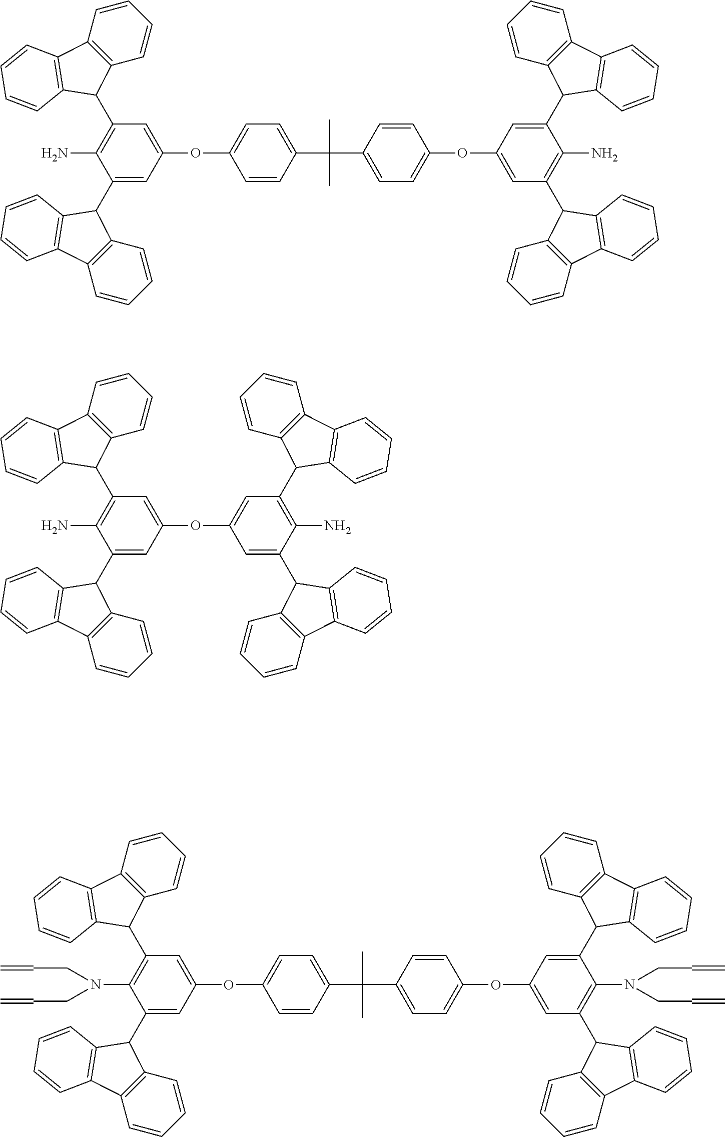 [SMILES: CC(C)(c1ccc(Oc2cc(C3c4ccccc4-c4ccccc43)c(N)c(C3c4ccccc4-c4ccccc43)c2)cc1)c1ccc(Oc2cc(C3c4ccccc4-c4ccccc43)c(N)c(C3c4ccccc4-c4ccccc43)c2)cc1 ; Nc1c(C2c3ccccc3-c3ccccc32)cc(Oc2cc(C3c4ccccc4-c4ccccc43)c(N)c(C3c4ccccc4-c4ccccc43)c2)cc1C1c2ccccc2-c2ccccc21 ; C=CCN(CC=C)c1c(C2c3ccccc3-c3ccccc32)cc(Oc2ccc(C(C)(C)c3ccc(Oc4cc(C5c6ccccc6-c6ccccc65)c(N(CC=C)CC=C)c(C5c6ccccc6-c6ccccc65)c4)cc3)cc2)cc1C1c2ccccc2-c2ccccc21]

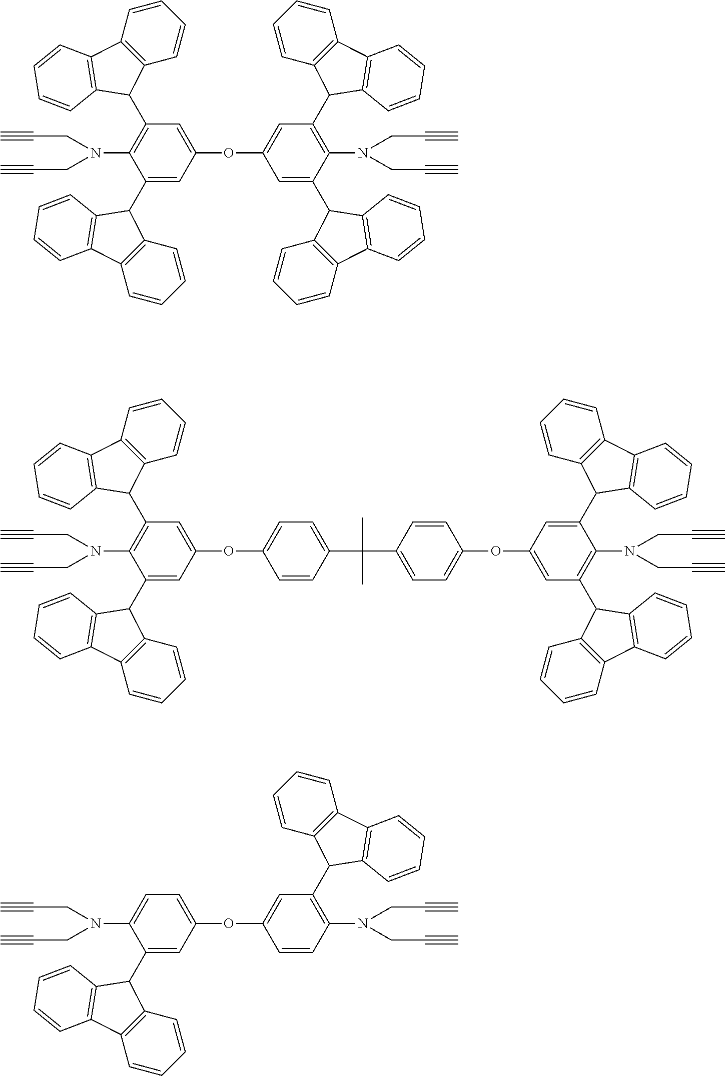

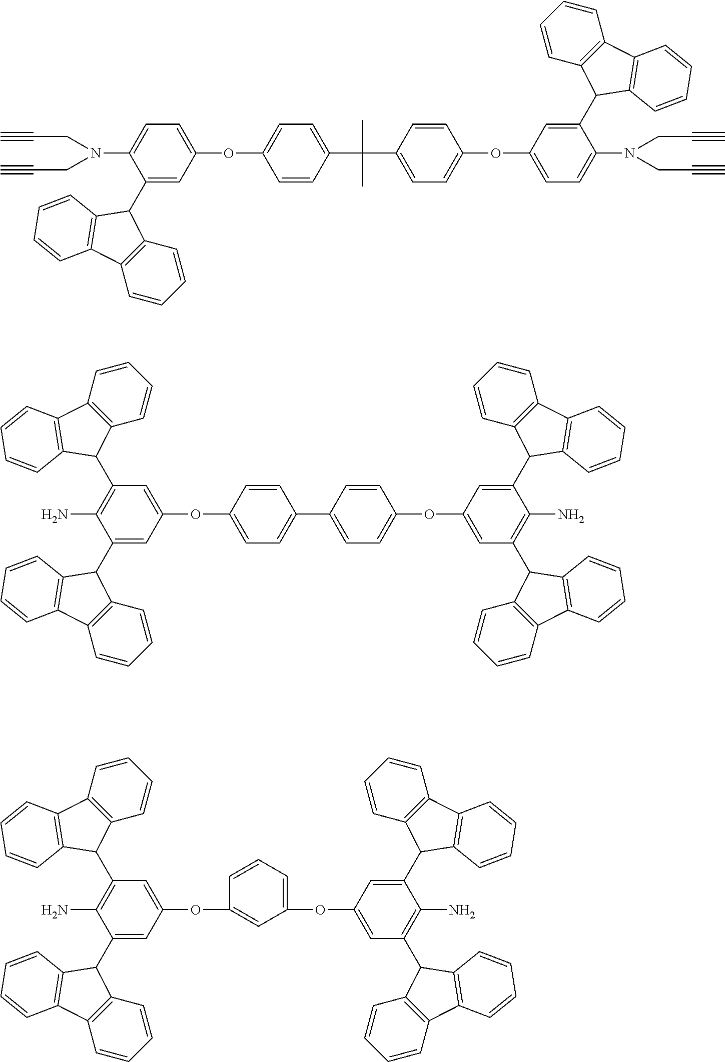 [SMILES: C#CCN(CC#C)c1ccc(Oc2ccc(C(C)(C)c3ccc(Oc4ccc(N(CC#C)CC#C)c(C5c6ccccc6-c6ccccc65)c4)cc3)cc2)cc1C1c2ccccc2-c2ccccc21 ; Nc1c(C2c3ccccc3-c3ccccc32)cc(Oc2ccc(-c3ccc(Oc4cc(C5c6ccccc6-c6ccccc65)c(N)c(C5c6ccccc6-c6ccccc65)c4)cc3)cc2)cc1C1c2ccccc2-c2ccccc21 ; Nc1c(C2c3ccccc3-c3ccccc32)cc(Oc2cccc(Oc3cc(C4c5ccccc5-c5ccccc54)c(N)c(C4c5ccccc5-c5ccccc54)c3)c2)cc1C1c2ccccc2-c2ccccc21]

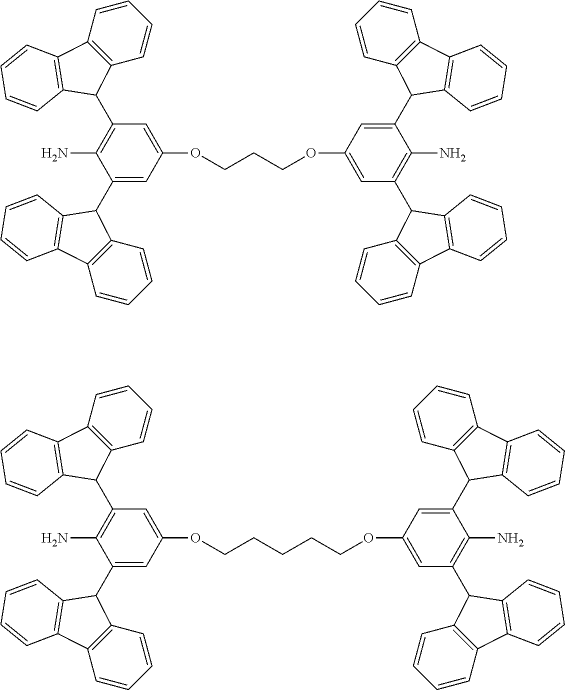 [SMILES: Nc1c(C2c3ccccc3-c3ccccc32)cc(OCCCOc2cc(C3c4ccccc4-c4ccccc43)c(N)c(C3c4ccccc4-c4ccccc43)c2)cc1C1c2ccccc2-c2ccccc21 ; Nc1c(C2c3ccccc3-c3ccccc32)cc(OCCCCCOc2cc(C3c4ccccc4-c4ccccc43)c(N)c(C3c4ccccc4-c4ccccc43)c2)cc1C1c2ccccc2-c2ccccc21]

### [Synthesis of Compound of Formula (A) or Formula (B)]

As a method of synthesizing a compound of Formula (A) or Formula (B), for example, a method in which an amine compound or diamine compound of the following Formula (C) to Formula (E) is reacted with a compound of Formula (G), a substituent R¹is introduced, a compound of Formula (F) is then reacted, and a substituent Ar¹ is introduced may be exemplified.

The order of introducing the substituent R¹ and the substituent Ar¹ may be reversed with respect to that described above or can be appropriately selected.

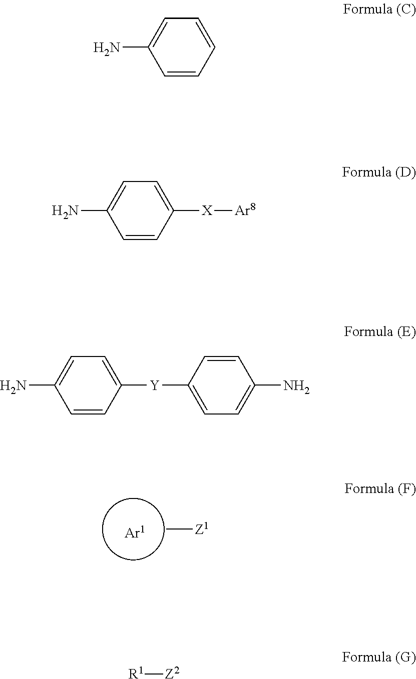

X, Y, Ar¹, and R are as described above. Ar⁸ is the same as Ar⁷ in Formula (A) described above.

Z¹ and Z² are groups capable of leaving such as a hydroxyl group, a halogen group, and a sulfo group, and Z¹ is preferably a hydroxyl group, and Z² is preferably a halogen group.

Reaction products preferably used in the present invention will be described in examples.

### [Solvent]

The solvent for the resist underlayer film-forming composition according to the present invention can be used without particular limitation as long as it is a solvent that can dissolve the reaction product. Particularly, since the resist underlayer film-forming composition according to the present invention is used in a uniform solution state, it is recommended to use in combination of a solvent generally used for a lithography process in consideration of the coating performance thereof.

Examples of such solvents include methyl cellosolve acetate, ethyl cellosolve acetate, propylene glycol, propylene glycol monomethyl ether, propylene glycol monoethyl ether, methyl isobutylcarbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butylate, methyl acetoacetate, toluene, xylene, methyl ethyl ketone, methyl propyl ketone, methy butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and 7-butyrolactone. These solvents can be used alone or two or more thereof can be used in combination.

In addition, the following compound described in WO2018/131562A1 can be used.

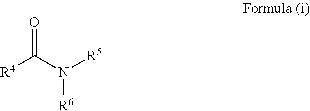

(in Formula (i), R⁴, R⁵ and R⁶ are each a hydrogen atom or a C₁₋₂₀ alkyl group which may be intervened by an oxygen atom, a sulfur atom or an amide bond, and may be the same as or different from each other, and may be bonded to each other to form a ring structure).

Examples of C₁₋₂₀ alkyl groups include a linear or branched alkyl group which may or may not have a substituent, and for example, methyl group, ethyl group, n-propyl group, isopropyl group, n-butyl group, sec-butyl group, tert-butyl group, n-pentyl group, isopentyl group, neopentyl group, n-hexyl group, isohexyl group, n-heptyl group, n-octyl group, cyclohexyl group, 2-ethylhexyl group, n-nonyl group, isononyl group, p-tert-butylcyclohexyl group, n-decyl group, n-dodecyl nonyl group, undecyl group, dodecyl group, tridecyl group, tetradecyl group, pentadecyl group, hexadecyl group, heptadecyl group, octadecyl group, nonadecyl group and eicosyl group. A C₁₋₁₂ alkyl group is preferable, a C₁₋₈ alkyl group is more preferable, and a C₁₋₄ alkyl group is still more preferable.

Examples of C₁₋₂₀ alkyl groups that are intervened by an oxygen atom, a sulfur atom or an amide bond include those having a structural unit —CH₂—O—, —CH₂—S—, —CH₂—NHCO— or —CH₂—CONH—. —O—, —S—, —NHCO— or —CONH— may be one unit or two or more units in the alkyl group. Specific examples of C₁₋₂₀ alkyl groups that may be intervened by an —O—, —S—, —NHCO— or —CONH— unit include methoxy group, ethoxy group, propoxy group, butoxy group, methylthio group, ethylthio group, propylthio group, butylthio group, methylcarbonylamino group, ethylcarbonylamino group, propylcarbonylamino group, butylcarbonylamino group, methylaminocarbonyl group, ethylaminocarbonyl group, propylaminocarbonyl group, and butylaminocarbonyl group, and additionally include methyl group, ethyl group, propyl group, butyl group, pentyl group, hexyl group, heptyl group, octyl group, nonyl group, decyl group, dodecyl group and octadecyl group, each of which is substituted with a methoxy group, ethoxy group, propoxy group, butoxy group, methylthio group, ethylthio group, propylthio group, butylthio group, methylcarbonylamino group, ethylcarbonylamino group, methylaminocarbonyl group, ethylaminocarbonyl group or the like. A methoxy group, ethoxy group, methylthio group, and ethylthio group are preferable, and a methoxy group and ethoxy group are more preferable.

Since these solvents have relatively high boiling points, they are effective to impart an improved embedding property and high flatness to the resist underlayer film-forming composition.

Specific examples of a preferable compound of Formula (i) are shown below.

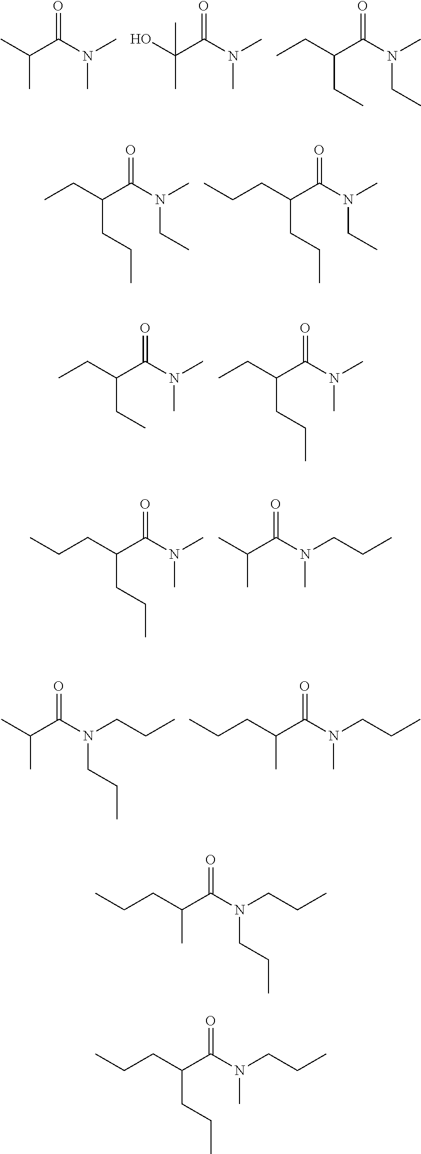

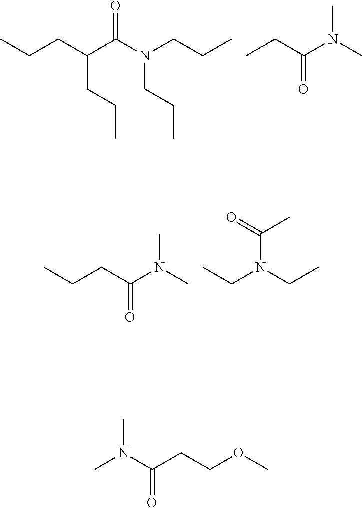

Among the above examples, 3-methoxy-N,N-dimethylpropionamide, N,N-dimethylisobutyramide, and a compound of the following formula:

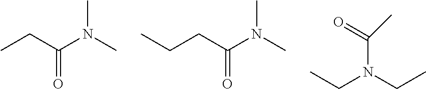

are preferable, and 3-methoxy-N,N-dimethylpropionamide and N,N-dimethylisobutyramide are particularly preferable compounds of Formula (i).

These solvents can be used alone or two or more thereof can be used in combination. Among these solvents, those having a boiling point of 160° C. or higher are preferable, and preferable examples thereof include propylene glycol monomethyl ether, propylene glycol monomethyl ether acetate, ethyl lactate, butyl lactate, cyclohexanone, 3-methoxy-N,N-dimethylpropionamide, N,N-dimethylisobutylamide, 2,5-dimethylhexane-1,6-diyl diacetate (DAH; cas, 89182-68-3), and 1,6-diacetoxyhexane (cas, 6222-17-9). Particularly preferable examples thereof include propylene glycol monomethyl ether, propylene glycol monomethyl ether acetate, and N,N-dimethylisobutylamide.

### [Crosslinking Agent Component]

The resist underlayer film-forming composition of the present invention may contain a crosslinking agent component. Examples of such crosslinking agents include a melamine-based agent, a substituted urea-based agent and polymers thereof. A crosslinking agent having at least two crosslink forming substituents is preferable, and compounds such as methoxymethylated glycoluril, butoxymethylated glycoluril, methoxymethylated melamine, butoxymethylated melamine, methoxymethylated benzogwanamine, butoxymethylated benzogwanamine, methoxymethylated urea, butoxymethylated urea, and methoxymethylated thiourea may be used. In addition, a condensate of these compounds can be used.

In addition, a crosslinking agent having high heat resistance can be used as the crosslinking agent. As the crosslinking agent having high heat resistance, a compound having a crosslink forming substituent having an aromatic ring (for example, a benzene ring and a naphthalene ring) in the molecule can be preferably used.

Examples of this compound include a compound having a substructure of the following Formula (4) and a polymer or oligomer having a repeating unit of the following Formula (5).

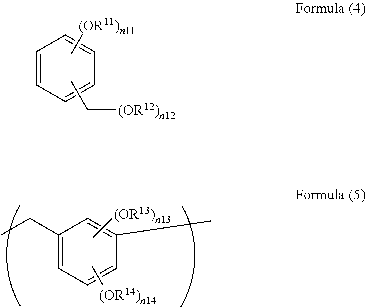

R¹¹, R¹², R¹³, and R¹⁴ are a hydrogen atom or a C₁₋₁₀ alkyl group, and the above examples can be used as these alkyl groups. n11 is an integer of 1 to 4, n12 is an integer of 1 to (5−n11), and (n11+n12) is an integer of 2 to 5. n13 is an integer of 1 to 4, n14 is 0 to (4−n13), and (n13+n14) is an integer of 1 to 4. Oligomers and polymers having a repeating unit structure number in a range of 2 to 100 or 2 to 50 can be used.

Compounds, polymers, and oligomers of Formula (4) and Formula (5) are exemplified below.

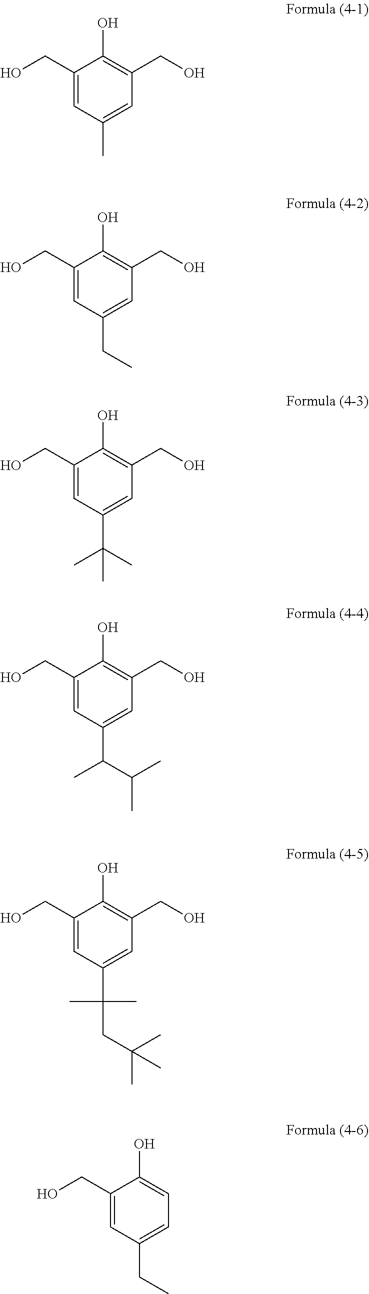

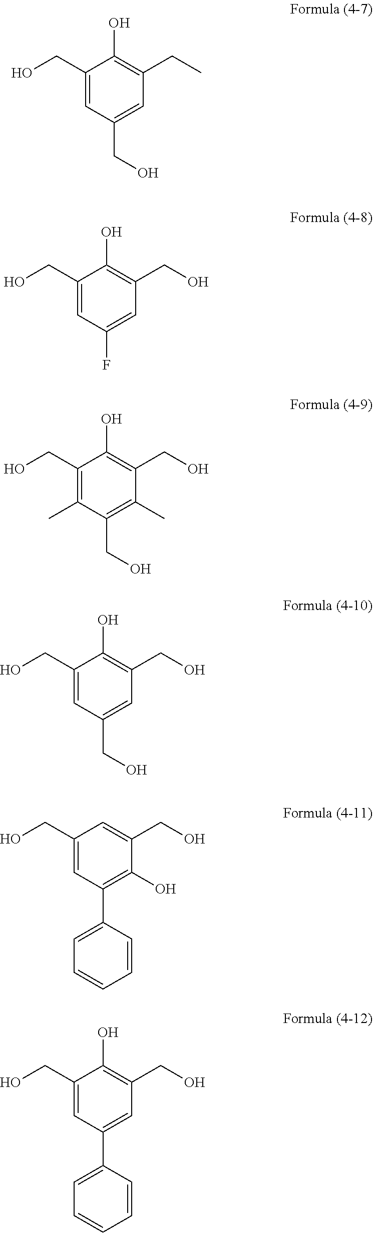

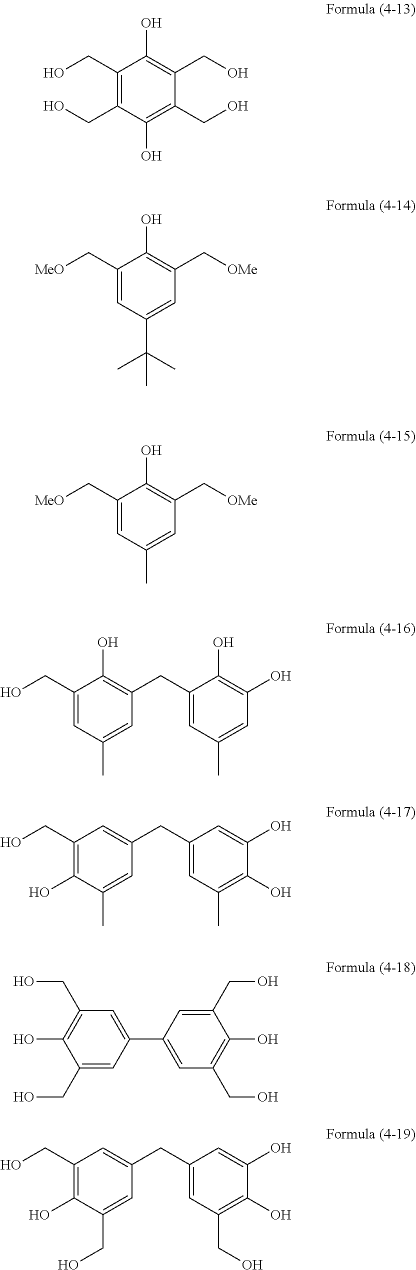

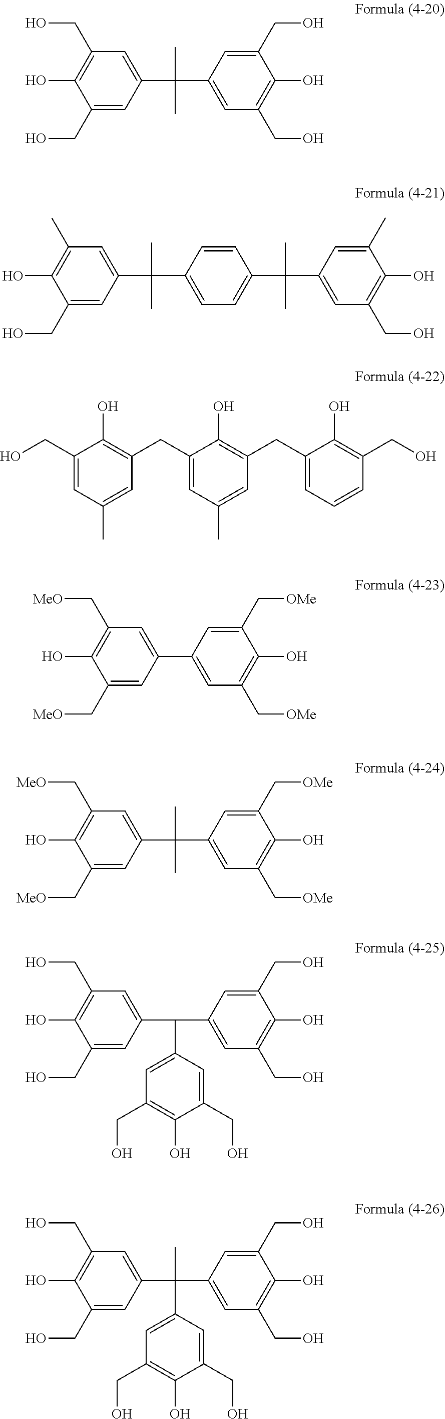

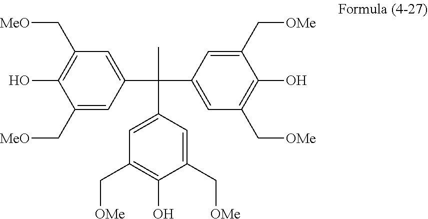 [SMILES: COCc1cc(C(C)(c2cc(COC)c(O)c(COC)c2)c2cc(COC)c(O)c(COC)c2)cc(COC)c1O]

The above compounds can be obtained as products (commercially available from Asahi Yukizai Corporation and commercially available from Honshu Chemical Industry Co., Ltd.). For example, among the above crosslinking agents, the compound of Formula (4-24) can be obtained as a product name TM-BIP-A (commercially available from Asahi Yukizai Corporation).

In addition to the above compounds, compounds having the following structures can also be used as crosslinking agents.

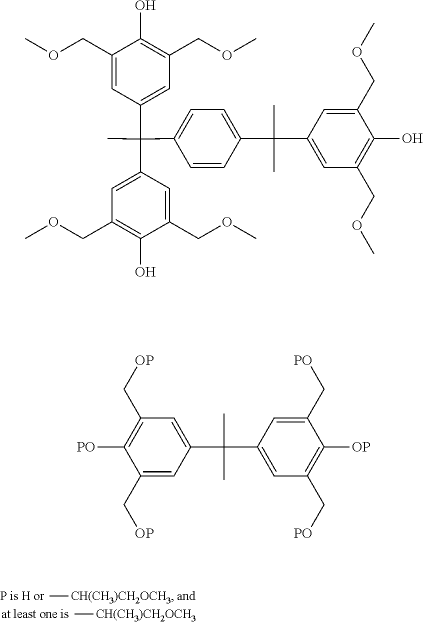

The amount of the crosslinking agent added varies depending on a coating solvent used, a base substrate used, a required solution viscosity, a required film shape and the like, but is 0.001 to 80% by mass, preferably 0.01 to 50% by mass, and more preferably 0.05 to 40% by mass with respect to the total solid content. These crosslinking agents may cause a cross-linking reaction according to self-condensation, but when crosslinkable substituents are present in the reaction product of the present invention, the crosslinking agent can cause a cross-linking reaction with these crosslinkable substituents.

[Acid and/or Acid Generating Agent]

The resist underlayer film-forming composition of the present invention can contain an acid and/or an acid generating agent.

Examples of acids include p-toluene sulfonic acid, trifluoromethane sulfonic acid, pyridinium p-toluene sulfonic acid, salicylic acid, 5-sulfosalicylic acid, 4-phenol sulfonic acid, camphor sulfonic acid, 4-chlorobenzene sulfonic acid, benzene disulfonic acid, 1-naphthalene sulfonic acid, citric acid, benzoic acid, hydroxybenzoic acid, and naphthalenecarboxylic acid.

Acids can be used alone, or two or more thereof can be used in combination. The amount of the acid added with respect to the total solid content is generally 0.0001 to 20% by mass, preferably 0.0005 to 10% by mass, and more preferably 0.01 to 5% by mass.

Examples of acid generating agents include a thermal acid generating agent and a photoacid generating agent. Examples of thermal acid generating agents include 2,4,4,6-tetrabromocyclohexadienone, benzoin tosylate, 2-nitrobenzyl tosylate, pyridinium-4-hydroxybenzenesulfonate, pyridinium-p-toluene sulfonate, pyridinium trifluoromethanesulfonate, N-(4-methoxybenzyl)-N,N-dimethyl anilinium triflate, and other organic sulfonic acid alkyl esters.

The photoacid generating agent generates an acid when the resist is exposed. Therefore, the acidity of the underlayer film can be adjusted. This is a method for adjusting the acidity of the underlayer film to the acidity of the upper layer resist. In addition, the pattern shape of the resist formed on the upper layer can be adjusted by adjusting the acidity of the underlayer film.

Examples of photoacid generating agents contained in the resist underlayer film-forming composition of the present invention include onium salt compounds, sulfonimide compounds, and disulfonyldiazomethane compounds.

Examples of onium salt compounds include iodonium salt compounds such as diphenyliodonium hexafluorophosphate, diphenyliodonium trifluoromethane sulfonate, diphenyliodonium nonafluoro normal butane sulfonate, diphenyliodonium perfluoro normal octane sulfonate, diphenyliodonium camphor sulfonate, bis(4-tert-butylphenyl) iodonium camphor sulfonate and bis(4-tert-butylphenyl)iodonium trifluoromethane sulfonate, and sulfonium salt compounds such as triphenylsulphonium hexafluoroantimonate, triphenylsulfonium nonafluoro normal butane sulfonate, triphenylsulfonium camphor sulfonate and triphenylsulfonium trifluoromethanesulfonate.

Examples of sulfonimide compounds include N-(trifluoromethanesulfonyloxy)succinimide, N-(nonafluoronormal butane sulfonyloxy)succinimide, N-(camphor sulfonyloxy)succinimide and N-(trifluoromethanesulfonyloxy)naphthalimide.

Examples of disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generating agents can be used alone or two or more thereof can be used in combination.

When an acid generating agent is used, the ratio thereof with respect to a solid content of 100 parts by mass of the resist underlayer film-forming composition is 0.01 to 5 parts by mass, 0.1 to 3 parts by mass, or 0.5 to 1 parts by mass.

### [Other Components]

In the resist underlayer film-forming composition of the present invention, in order to prevent pinholes, striations or the like from being generated and further improve coverage against surface unevenness, a surfactant can be added. Examples of surfactants include non-ionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octylphenol ether and polyoxyethylene nonylphenol ether, sorbitan fatty acid esters such as polyoxyethylene/polyoxypropylene block copolymers, sorbitan monolaurate, sorbitan monopalmitate, sorbitan monostearate, sorbitan monooleate, sorbitan trioleate, and sorbitan tristearate, polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine-based surfactants such as Eftop EF301, EF303, and EF352 (product name, commercially available from Tochem Products Co., Ltd.), Megaface F171, F173, R-30N, R-40, R-40N, and R-40LM (product name, commercially available from DIC Corporation), Fluorad FC430, and FC431 (product name, commercially available from Sumitomo 3M Ltd.), AsahiGuard AG710, Surflon S-382, SC101, SC102, SC103, SC104, SC105, and SC106 (product name, commercially available from Asahi Glass Co., Ltd.), and organosiloxane polymer KP341 (commercially available from Shin-Etsu Chemical Co., Ltd.). The amount of this surfactant added with respect to a total solid content of the resist underlayer film material is generally 2.0% by mass or less, and preferably 1.0% by mass or less. These surfactants can be used alone or two or more thereof can be used in combination. When the surfactant is used, the ratio thereof with respect to a solid content of 100 parts by mass of the resist underlayer film-forming composition is 0.0001 to 5 parts by mass, 0.001 to 1 parts by mass, or 0.01 to 0.5 parts by mass.

In the resist underlayer film-forming composition of the present invention, a light absorbing agent, a rheology adjusting agent, an adhesive auxiliary agent or the like can be added. The rheology adjusting agent is effective in improving the fluidity of the underlayer film-forming composition. The adhesive auxiliary agent is effective in improving the adhesion between the semiconductor substrate or the resist and the underlayer film.

As the light absorbing agent, for example, commercially available light absorbing agents described in “A Technology and Market of Industrial Dyes” (CMC publishing) and “A Handbook of Dyes” (edited by The Society of Synthetic Organic Chemistry), for example, C. I. Disperse Yellow 1, 3, 4, 5, 7, 8, 13, 23, 31, 49, 50, 51, 54, 60, 64, 66, 68, 79, 82, 88, 90, 93, 102, 114 and 124; C. I. Disperse Orange 1, 5, 13, 25, 29, 30, 31, 44, 57, 72 and 73; C. I. Disperse Red 1, 5, 7, 13, 17, 19, 43, 50, 54, 58, 65, 72, 73, 88, 117, 137, 143, 199 and 210; C. I. Disperse Violet 43; C. I. Disperse Blue 96; C. I. Fluorescent Brightening Agent 112, 135 and 163; C. I. Solvent Orange 2 and 45; C. I. Solvent Red 1, 3, 8, 23, 24, 25, 27 and 49; C. I. Pigment Green 10; C. I. Pigment Brown 2 and the like can be suitably used. The light absorbing agent is generally added in a proportion of 10% by mass or less, and preferably 5% by mass or less with respect to a total solid content of the resist underlayer film-forming composition.

The rheology adjusting agent is mainly added in order to improve the fluidity of the resist underlayer film-forming composition, and improve the uniformity of the film thickness of the resist underlayer film particularly in a baking step and improve the ability of the resist underlayer film-forming composition to fill the hole. Specific examples include phthalic acid derivatives such as dimethyl phthalate, diethyl phthalate, diisobutyl phthalate, dihexyl phthalate, and butylisodecyl phthalate, adipic acid derivatives such as dinormal butyl adipate, diisobutyl adipate, diisooctyl adipate, and octyldecyl adipate, maleic acid derivatives such as dinormal butyl malate, diethyl malate, and dinonyl malate, oleic acid derivatives such as methyl oleate, butyl oleate, and tetrahydrofurfuryl oleate, and stearic acid derivatives such as normal butyl stearate and glyceryl stearate. This rheology adjusting agent is generally added in a proportion of less than 30% by mass with respect to a total solid content of the resist underlayer film-forming composition.

The adhesive auxiliary agent is mainly added in order to improve the adhesion between the substrate or the resist and the resist underlayer film-forming composition, and prevent the resist from peeling off particularly during development. Specific examples include chlorosilanes such as trimethylchlorosilane, dimethylmethylolchlorosilane, methyldiphenylchlorosilane, and chloromethyldimethylchlorosilane, alkoxysilanes such as trimethylmethoxysilane, dimethyldiethoxysilane, methyldimethoxysilane, dimethylmethylolethoxysilane, diphenyldimethoxysilane, and phenyltriethoxysilane, silazanes such as hexamethyl disilazane, N,N′-bis(trimethylsilyl)urea, dimethyltrimethylsilylamine, and trimethylsilylimidazole, silanes such as methyloltrichlorosilane, γ-chloropropyltrimethoxysilane, γ-aminopropyltriethoxysilane, and γ-glycidoxypropyltrimethoxysilane, heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine, ureas such as 1,1-dimethyl urea and 1,3-dimethyl urea, and thiourea compounds. This adhesive auxiliary agent is added in a proportion of generally less than 5% by mass, and preferably less than 2% by mass with respect to a total solid content of the resist underlayer film-forming composition.

The solid content of the resist underlayer film-forming composition according to the present invention is generally 0.1 to 70% by mass, and preferably 0.1 to 60% by mass. The solid content is the content of all components excluding the solvent from the resist underlayer film-forming composition. The proportion of the reaction product in the solid content is preferably 1 to 100% by mass, 1 to 99.9% by mass, 50 to 99.9% by mass, 50 to 95% by mass, and 50 to 90% by mass in this order.

One scale for evaluating whether the resist underlayer film-forming composition is in a uniform solution state is observation of passability using a specific micro filter, but the resist underlayer film-forming composition according to the present invention passes through a micro filter having a pore size of 0.1 m and exhibits a uniform solution state.

Examples of materials for the microfilter include fluorine resins such as polytetrafluoroethylene (PTFE), and tetrafluoroethylene-perfluoroalkyl vinyl ether (PFA) copolymers, polyethylene (PE), ultra-high-molecular-weight polyethylene (UPE), polypropylene (PP), polysulfone (PSF), polyethersulfone (PES), and nylon, and one made of polytetrafluoroethylene (PTFE) is preferable.

### [Method for Producing Resist Underlayer Film and Semiconductor Device]

Hereinafter, a method for producing a resist underlayer film and a semiconductor device using the resist underlayer film-forming composition according to the present invention will be described.

The resist underlayer film-forming composition of the present invention is applied onto a substrate (for example, a silicon wafer substrate, a silicon/silicon dioxide-coated substrate, a silicon nitride substrate, a glass substrate, an ITO substrate, a polyimide substrate, and a low-dielectric constant material (low-k material)-coated substrate, etc.) used for producing a semiconductor device by an appropriate coating method such as using a spinner or a coater, and the resist underlayer film is then formed by baking. Baking conditions are appropriately selected from a baking temperature of 80° C. to 500° C. and a baking time of 0.3 to 60 minutes. Preferably, the baking temperature is 150° C. to 400° C., and the baking time is 0.5 to 2 minutes. Here, the film thickness of the underlayer film formed is, for example, 10 to 1,000 nm, 20 to 500 nm, 30 to 300 nm, or 50 to 200 nm.

As the baking atmosphere, either air or a nitrogen atmosphere can be selected.

In addition, an inorganic resist underlayer film (hard mask) can be formed on the organic resist underlayer film according to the present invention. For example, in addition to the method of forming the silicon-containing resist underlayer film (inorganic resist underlayer film) forming composition described in WO2009/104552A1 by spin coating, a Si-based inorganic material film can be formed by a CVD method or the like.

In addition, the resist underlayer film-forming composition according to the present invention is applied onto a semiconductor substrate (so-called step substrate) having a part having a step and a part having no step, and baked, and thus a resist underlayer film in which the step between the part having a step and the part having no step is in a range of 3 to 50 nm can be formed.

Next, a resist film, for example, a photoresist layer, is formed on the resist underlayer film. The photoresist layer can be formed by a well-known method, that is, application of the photoresist composition solution onto the underlayer film and baking it. The film thickness of the photoresist is, for example, 50 to 10,000 nm, 100 to 2,000 nm, or 200 to 1,000 nm.

The photoresist to be formed on the resist underlayer film is not particularly limited as long as it is sensitive to light used for exposure. Both a negative type photoresist and a positive type photoresist can be used. Examples thereof include a positive type photoresist composed of a novolac resin and 1,2-naphthoquinone diazide sulfonic acid ester; a chemically amplified photoresist composed of a binder having a group that is decomposed by an acid to increase an alkali dissolution rate, and a photoacid generating agent; a chemically amplified photoresist composed of a low-molecular-weight compound that is decomposed by an acid to increase an alkali dissolution rate of a photoresist, an alkali-soluble binder and a photoacid generating agent; and a chemically amplified photoresist composed of a binder having a group that is decomposed by an acid to increase an alkali dissolution rate, a low-molecular-weight compound that is decomposed by an acid to increase an alkali dissolution rate of a photoresist, and a photoacid generating agent. For example, product name APEX-E (commercially available from Shipley Company), product name PAR710 (commercially available from Sumitomo Chemical Co., Ltd.), and product name SEPR430 (commercially available from Shin-Etsu Chemical Co., Ltd.) may be exemplified. In addition, for example, fluorine-containing atomic polymer-based photoresists described in Proc. SPIE, Vol. 3999, 330-334 (2000), Proc. SPIE, Vol. 3999, 357-364 (2000), and Proc. SPIE, Vol. 3999, 365-374 (2000) may be exemplified.

Next, a resist pattern is formed by emitting light or an electron beam and development. First, exposure is performed through a predetermined mask. For exposure, near ultraviolet rays, far ultraviolet rays, or extreme ultraviolet rays (for example, EUV (a wavelength of 13.5 nm)) are used. Specifically, a KrF excimer laser (a wavelength of 248 nm), an ArF excimer laser (a wavelength of 193 nm), an F₂ excimer laser (a wavelength of 157 nm) or the like can be used. Among these, an ArF excimer laser (a wavelength of 193 nm) and EUV (a wavelength of 13.5 nm) are preferable. After exposure, heating after exposure (post exposure bake) can be performed as necessary. Heating after exposure is performed under conditions appropriately selected from a heating temperature of 70° C. to 150° C. and a heating time of 0.3 to 10 minutes.

In addition, in the present invention, as the resist, a resist for electron beam lithography can be used instead of a photoresist. Both a negative type and a positive type can be used as the electron beam resist. Examples thereof include a chemically amplified resist composed of an acid generating agent and a binder having a group that is decomposed by an acid to change an alkali dissolution rate; a chemically amplified resist composed of an alkali-soluble binder, an acid generating agent and a low-molecular-weight compound that is decomposed by an acid to change an alkali dissolution rate of a resist; a chemically amplified resist composed of an acid generating agent, a binder having a group that is decomposed by an acid to change an alkali dissolution rate, and a low-molecular-weight compound that is decomposed by an acid to change an alkali dissolution rate of a resist; a non-chemically amplified resist composed of a binder having a group that is decomposed by an electron beam to change an alkali dissolution rate; and a non-chemically amplified resist composed of a binder having a moiety that is cut by an electron beam to change an alkali dissolution rate. Even when these electron beam resists are used, a resist pattern can be formed in the same manner as when a photoresist is used with an electron beam as a light emission source.

Next, development is performed with a developing solution. Accordingly, for example, when a positive type photoresist is used, the photoresist of the exposed part is removed, and the pattern of the photoresist is formed.

Examples of developing solutions include aqueous solutions containing alkaline metal hydroxides such as potassium hydroxide and sodium hydroxide, aqueous solutions containing quaternary ammonium hydroxide such as tetramethylammonium hydroxide, tetraethylammonium hydroxide, and choline, and alkaline aqueous solutions such as aqueous solutions containing amines such as ethanolamine, propylamine, and ethylenediamine. In addition, a surfactant and the like can be added to these developing solutions. The development conditions are appropriately selected from among a temperature of 5 to 50° C. and a time of 10 to 600 seconds.

Then, the inorganic underlayer film (intermediate layer) is removed using the pattern of the photoresist (upper layer) formed in this manner as a protective film, and the organic underlayer film (lower layer) is then removed using a film composed of the patterned photoresist and inorganic underlayer film (intermediate layer) as a protective film. Finally, the semiconductor substrate is processed using the patterned inorganic underlayer film (intermediate layer) and organic underlayer film (lower layer) as a protective film.

First, the inorganic underlayer film (intermediate layer) of the part in which the photoresist has been removed is removed by dry etching, and the semiconductor substrate is exposed. For dry etching of the inorganic underlayer film, gases such as tetrafluoromethane (CF₄), perfluorocyclobutane (C₄F₈), perfnuoropropane (C₃F8), trifluoromethane, carbon monoxide, argon, oxygen, nitrogen, sulfur hexafluoride, difluoromethane, nitrogen trifluoride, chlorine trifluoride, chlorine, trichloroborane and dichloroborane can be used. For dry etching of the inorganic underlayer film, it is preferable to use a halogen-based gas, and more preferable to use fluorine gas. Examples of fluorine gases include tetrafluoromethane (CF₄), perfluorocyclobutane (C₄F₈), perfluoropropane (C₃F₈), trifluoromethane, and difluoromethane (CH₂F₂).

Then, the organic underlayer film is removed using the film composed of the patterned photoresist and inorganic underlayer film as a protective film. The organic underlayer film (lower layer) is preferably dry-etched using an oxygen-based gas. This is because the inorganic underlayer film containing a large amount of silicon atoms is unlikely to be removed by dry etching using an oxygen-based gas.

Finally, the semiconductor substrate is processed. The semiconductor substrate is preferably processed by dry etching using a fluorine gas.

Examples of fluorine gases include tetrafluoromethane (CF₄), perfluorocyclobutane (C₄F₈), perfluoropropane (C₃F₈), trifluoromethane, and difluoromethane (CH₂F₂).

In addition, an organic anti-reflective coating can be formed on the upper layer of the resist underlayer film before the photoresist is formed. The anti-reflective coating composition used here is not particularly limited, and one arbitrarily selected from among those commonly used in lithography processes can be used, and the anti-reflective coating can be formed by a commonly used method, for example, coating with a spinner or a coater and baking.

In the present invention, the organic underlayer film is formed on the substrate and the inorganic underlayer film is then formed thereon, and a photoresist can be additionally coated thereon. Accordingly, the pattern width of the photoresist becomes narrower, and even if the photoresist is thinly coated to prevent pattern collapse, the substrate can be processed by selecting an appropriate etching gas. For example, it is possible to process the resist underlayer film using fluorine gas as an etching gas at a sufficiently high etching rate for the photoresist, it is possible to process the substrate using fluorine gas as an etching gas at a sufficiently high etching rate for the inorganic underlayer film, and it is also possible to process the substrate using an oxygen-based gas as an etching gas at a sufficiently high etching rate for the organic underlayer film.

Depending on the wavelength of light used in the lithography process, the resist underlayer film formed from the resist underlayer film-forming composition may also absorb the light. Thus, in such a case, it can function as an anti-reflective coating having an effect of preventing reflected light from the substrate. In addition, the underlayer film formed from the resist underlayer film-forming composition of the present invention can also function as a hard mask. The underlayer film of the present invention can also be used as a layer for preventing an interaction between the substrate and the photoresist, a layer having a function of preventing an adverse effect of the material used in the photoresist or the substance generated during exposure to the photoresist on the substrate, a layer having a function of preventing the substance generated from the substrate during heating and baking from diffusing into the upper layer photoresist, a barrier layer for reducing the poisoning effect of the photoresist layer by a semiconductor substrate dielectric layer, or the like.

In addition, the underlayer film formed of the resist underlayer film-forming composition can be applied to a substrate with a via hole formed that is used in a dual damascene process, and can be used as an embedding material that can fill the hole without gaps. In addition, it can also be used as a flattening material for flattening the uneven surface of the semiconductor substrate.

### EXAMPLES

The weight-average molecular weight and polydispersity shown in the following Synthesis Example 1 were based on the results of measurement by gel permeation chromatography (hereinafter, abbreviated as GPC in this specification). For the measurement, a GPC device (commercially available from Tosoh Corporation) was used, and measurement conditions were as follows.
GPC column: TSKgel SuperMultipore [registered trademark] Hz-N(commercially available from Tosoh Corporation))
Column temperature: 40° C.
Solvent: tetrahydrofuran (THF)
Flow rate: 0.35 mL/min
Standard sample: polystyrene (commercially available from Tosoh Corporation))

### Synthesis Example 1

Under nitrogen, 2,2-bis[4-(4-aminophenoxy)phenyl]propane (50.00 g, 0.1219 mol, commercially available from Tokyo Chemical Industry Co., Ltd.), 9-fluorenol (88.85 g, 0.4876 mol, commercially available from Tokyo Chemical Industry Co., Ltd.), and methane sulfonic acid (25.77 g, 0.2682 mol, commercially available from Tokyo Chemical Industry Co., Ltd.) were put into a 1,000 mL four-neck flask, propylene glycol 1-monomethyl ether 2-acetate (268.89 g, commercially available from Kanto Chemical Co., Inc.) and 1-methyl-2-pyrrolidone (115.24 g, commercially available from Tokyo Chemical Industry Co., Ltd.) were additionally put thereinto, the mixture was stirred and heated to 160° C. and dissolved, and the reaction started. After 24 hours, the mixture was cooled to room temperature and reprecipitated in a mixed solution containing methanol (3,600 g, commercially available from Kanto Chemical Co., Inc.) and ammonia water (190 g, commercially available from Kanto Chemical Co., Inc.). The obtained precipitate was filtered and dried in a vacuum dryer at 60° C. for 10 hours to obtain 95.5 g of a compound having a structure of the following Formula (a) (hereinafter, abbreviated as BAPP-4F in this specification). BAPP-4F had a weight-average molecular weight Mw of 720 and a polydispersity Mw/Mn of 1.10, which were measured by GPC in terms of polystyrene.

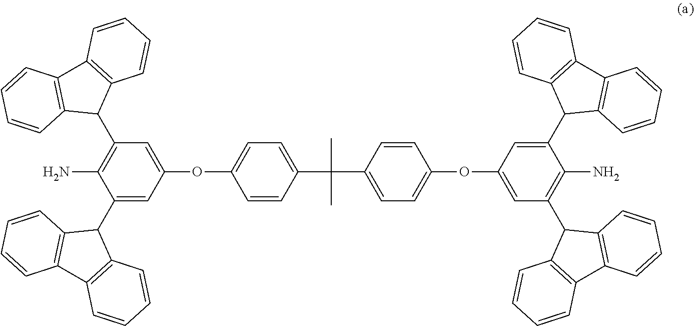 [SMILES: CC(C)(c1ccc(Oc2cc(C3c4ccccc4-c4ccccc43)c(N)c(C3c4ccccc4-c4ccccc43)c2)cc1)c1ccc(Oc2cc(C3c4ccccc4-c4ccccc43)c(N)c(C3c4ccccc4-c4ccccc43)c2)cc1]

### Synthesis Example 2

Under nitrogen, 1,3-bis(4-aminophenoxy)propane (40.00 g, 0.1549 mol, commercially available from Wako Pure Chemical Industries, Ltd.), 9-fluorenol (112.87 g, 0.6194 mol, commercially available from Tokyo Chemical Industry Co., Ltd.), and methane sulfonic acid (32.74 g, 0.3406 mol, commercially available from Tokyo Chemical Industry Co., Ltd.) were put into a 1,000 mL four-neck flask, propylene glycol 1-monomethyl ether 2-acetate (303.17 g, commercially available from Kanto Chemical Co., Inc.) and 1-methyl-2-pyrrolidone (129.93 g, commercially available from Tokyo Chemical Industry Co., Ltd.) were additionally put thereinto, the mixture was stirred and heated to 160° C. and dissolved, and the reaction started. After 24 hours, the mixture was cooled to room temperature and reprecipitated in a mixed solution containing methanol (3,600 g, commercially available from Kanto Chemical Co., Inc.) and ammonia water (190 g, commercially available from Kanto Chemical Co., Inc.). The obtained precipitate was filtered and dried in a vacuum dryer at 60° C. for 10 hours to obtain 74.24 g of a compound having a structure of the following Formula (b) (hereinafter, abbreviated as DA-3MG-4F in this specification). DA-3MG-4F had a weight-average molecular weight Mw of 660 and a polydispersity Mw/Mn of 1.40, which were measured by GPC in terms of polystyrene.

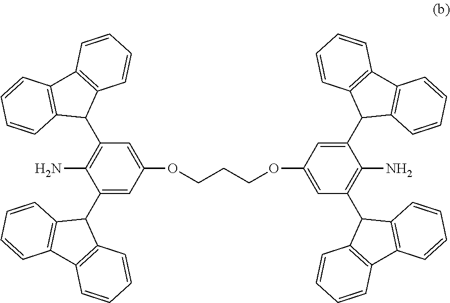 [SMILES: Nc1c(C2c3ccccc3-c3ccccc32)cc(OCCCOc2cc(C3c4ccccc4-c4ccccc43)c(N)c(C3c4ccccc4-c4ccccc43)c2)cc1C1c2ccccc2-c2ccccc21]

### Synthesis Example 3

Under nitrogen, 1,5-bis(4-aminophenoxy)pentane (40.00 g, 0.1397 mol, commercially available from Wako Pure Chemical Industries, Ltd.), 9-fluorenol (101.80 g, 0.5587 mol, commercially available from Tokyo Chemical Industry Co., Ltd.), and methane sulfonic acid (29.53 g, 0.3073 mol, commercially available from Tokyo Chemical Industry Co., Ltd.) were put into a 1,000 mL four-neck flask, propylene glycol 1-monomethyl ether 2-acetate (279.84 g, commercially available from Kanto Chemical Co., Inc.) and 1-methyl-2-pyrrolidone (119.93 g, commercially available from Tokyo Chemical Industry Co., Ltd.) were additionally put thereinto, the mixture was stirred and heated to 160° C. and dissolved, and the reaction started. After 24 hours, the mixture was cooled to room temperature and reprecipitated in a mixed solution containing methanol (3,600 g, commercially available from Kanto Chemical Co., Inc.) and ammonia water (190 g, commercially available from Kanto Chemical Co., Inc.). The obtained precipitate was filtered and dried in a vacuum dryer at 60° C. for 10 hours to obtain 77.10 g of a compound having a structure of the following Formula (c) (hereinafter, abbreviated as DA-5MG-4F in this specification). DA-5MG-4F had a weight-average molecular weight Mw of 680 and a polydispersity Mw/Mn of 1.40, which were measured by GPC in terms of polystyrene.

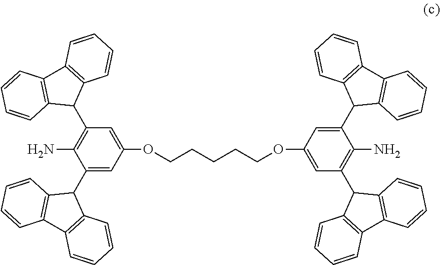 [SMILES: Nc1c(C2c3ccccc3-c3ccccc32)cc(OCCCCCOc2cc(C3c4ccccc4-c4ccccc43)c(N)c(C3c4ccccc4-c4ccccc43)c2)cc1C1c2ccccc2-c2ccccc21]

### Synthesis Example 4

Under nitrogen, 2,2-bis[4-(4-aminophenoxy)phenyl]propane (50.00 g, 0.1219 mol, commercially available from Tokyo Chemical Industry Co., Ltd.), potassium carbonate (134.66 g, 0.974 mol, commercially available from Tokyo Chemical Industry Co., Ltd.), and hydroquinone (0.75 g, 0.007 mol, commercially available from Tokyo Chemical Industry Co., Ltd.) were put into a 1,000 mL four-neck flask, dimethylformamide (500.00 g, commercially available from Kanto Chemical Co., Inc.) was additionally put thereinto, the mixture was stirred and heated to 40° C., propargyl bromide (101,423 g, 0.853 mol, commercially available from Tokyo Chemical Industry Co., Ltd.) was then added dropwise through a dropping funnel, and the reaction started. After 24 hours, the mixture was cooled to room temperature, the potassium carbonate residue was removed, toluene (500.00 g, commercially available from Kanto Chemical Co., Inc.) was then added and washing with pure water (500 g) was performed. The toluene solution was collected and distilled under a reduced pressure to obtain 55.3 g of an intermediate product (hereinafter, abbreviated as BAPP-PG in this specification).

Under nitrogen, BAPP-PG (40.00 g, 0.070 mol), 9-fluorenol (25.92 g, 0.142 mol, commercially available from Tokyo Chemical Industry Co., Ltd.), and methane sulfonic acid (13.67 g, 0.1423 mol, commercially available from Tokyo Chemical Industry Co., Ltd.) were put into a 1,000 mL four-neck flask, propylene glycol 1-monomethyl ether 2-acetate (145.7 g, commercially available from Kanto Chemical Co., Inc.) was additionally put thereinto, the mixture was stirred and heated to 140° C. and dissolved, and the reaction started. After 24 hours, the mixture was cooled to room temperature and reprecipitated in a mixed solution containing methanol (3,600 g, commercially available from Kanto Chemical Co., Inc.) and ammonia water (190 g, commercially available from Kanto Chemical Co., Inc.). The obtained precipitate was filtered and dried in a vacuum dryer at 40° C. for 10 hours to obtain 38.3 g of a compound having a structure of the following Formula (d) (hereinafter, abbreviated as BAPP-PG2F in this specification). BAPP-PG2F had a weight-average molecular weight Mw of 1,270 and a polydispersity Mw/Mn of 1.30, which were measured by GPC in terms of polystyrene.

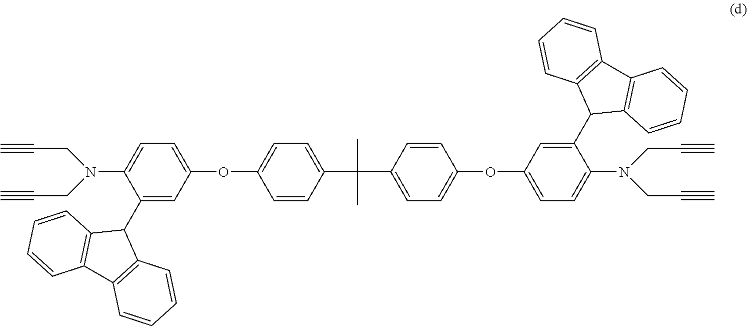 [SMILES: C#CCN(CC#C)c1ccc(Oc2ccc(C(C)(C)c3ccc(Oc4ccc(N(CC#C)CC#C)c(C5c6ccccc6-c6ccccc65)c4)cc3)cc2)cc1C1c2ccccc2-c2ccccc21]

### Example 1

A resist underlayer film-forming composition was prepared by dissolving 1.00 g of the compound of Formula (a) and 0.002 g of a surfactant (trade name: Megaface [product name] R-30N, fluorine-based surfactant, commercially available from DIC Corporation) in 4.92 g of propylene glycol monomethyl ether and 11.47 g of propylene glycol monomethyl ether acetate.

### Example 2

A resist underlayer film-forming composition was prepared by dissolving 1.00 g of the compound of Formula (a), 0.20 g of a polymer-type crosslinking agent having a structure of the following Formula (e) (hereinafter, abbreviated as TMOM-BPp in this specification) as a crosslinking agent, and 0.002 g of a surfactant (trade name: Megaface [product name] R-30N, fluorine-based surfactant, commercially available from DIC Corporation) in 5.88 g of propylene glycol monomethyl ether and 13.72 g of propylene glycol monomethyl ether acetate.

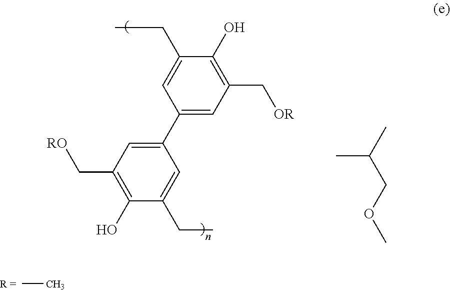

### Example 3

A resist underlayer film-forming composition was prepared by dissolving 1.00 g of the compound of Formula (b) and 0.002 g of a surfactant (trade name: Megaface [product name] R-30N, fluorine-based surfactant, commercially available from DIC Corporation) in 4.55 g of propylene glycol monomethyl ether and 10.63 g of propylene glycol monomethyl ether acetate.

### Example 4

A resist underlayer film-forming composition was prepared by dissolving 1.00 g of the compound of Formula (c) and 0.002 g of a surfactant (trade name: Megaface [product name] R-30N, fluorine-based surfactant, commercially available from DIC Corporation) in 4.71 g of propylene glycol monomethyl ether and 10.99 g of propylene glycol monomethyl ether acetate.

### Example 5

A resist underlayer film-forming composition was prepared by dissolving 1.00 g of the compound of Formula (d) and 0.002 g of a surfactant (trade name: Megaface [product name] R-30N, fluorine-based surfactant, commercially available from DIC Corporation) in 4.92 g of propylene glycol monomethyl ether and 11.47 g of propylene glycol monomethyl ether acetate.

### Comparative Example 1

A resist underlayer film-forming composition was prepared by dissolving 1.00 g of the polymer of the following Formula (f), 0.20 g of 4,4′-(1-methylethyridine)bis[2,6-bis[(2-methoxy-1-methylethoxy)methyl]-phenol as a crosslinking agent, 0.033 g of pyridinium p-phenol sulfonate as an acid catalyst, and 0.001 g of a surfactant (trade name: Megaface [product name] R-30N, fluorine-based surfactant, commercially available from DIC Corporation) in 4.93 g of propylene glycol monomethyl ether and 11.52 g of propylene glycol monomethyl ether acetate.

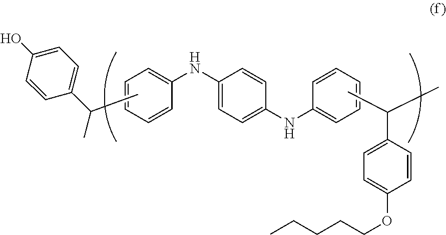

### (Test of Dissolving in Photoresist Solvent)

Each of the resist underlayer film-forming compositions prepared in Examples 1 to 5 and Comparative Example 1 was applied onto a silicon wafer using a spin coater. A resist underlayer film (a film thickness of 0.10 km) was formed by performing baking on a hot plate at 240° C. for 1 minute and additionally at 400° C. for 1 minute. This resist underlayer film was immersed in propylene glycol monomethyl ether and propylene glycol monomethyl ether acetate, which are solvents used for the resist, and it was confirmed that it was insoluble in these solvents.

### (Test of Coating on Step Substrate)

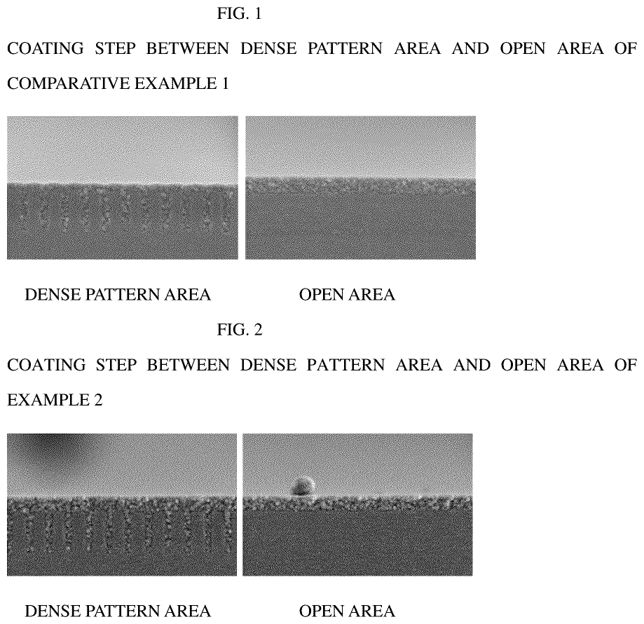

For evaluation of step coverage, a SiO₂ substrate with a trench pattern formed with a width of 50 nm, a pitch width of 50 nm, and a depth of 200 nm was used. Coating film thicknesses of a dense pattern area (DENSE) in which patterns with a trench width of 100 nm and a pitch of 175 nm were densely formed and an open area (OPEN) 1,400 km away therefrom in which no pattern was formed were compared. The resist underlayer film-forming composition of Examples 1 to 5 and Comparative Example 1 was applied onto the substrate at a film thickness of 100 nm and then baked at 240° C. for 60 seconds, and additionally at 400° C. for 60 seconds. The step coverage of the substrate was observed using a scanning electron microscope (S-4800) (commercially available from Hitachi High-Tech Corporation), and the flatness was evaluated by measuring the film thickness difference (the coating step between the dense pattern area and the open area, which is called Bias) between the dense pattern area (pattern part) and the open area (pattern-free part) of the step substrate. Table 1 shows the values of the film thickness and the coating step of each area, and FIG. 1 and FIG. 2 show SEM images of Comparative Example 1 and Example 2. In the flatness evaluation, a smaller Bias value indicates higher flatness.

[Table 1]

TABLE 1
Flatness test on trench wafer

| | Film thickness | Film thickness | |
|---|---|---|---|
| Resist underlayer film | (pattern part) | (pattern-free part) | Bias |
| Comparative Example 1 | 106 nm | 77 nm | 29 nm |
| Example 1 | 101 nm | 85 nm | 16 nm |
| Example 2 | 101 nm | 99 nm | 2 nm |
| Example 3 | 95 nm | 81 nm | 14 nm |
| Example 4 | 95 nm | 79 nm | 16 nm |
| Example 5 | 93 nm | 85 nm | 8 nm |

Comparing the coverage of step substrates, in the results of Examples 1 to 5, since the coating step between the pattern area and the open area was smaller than that of the result of Comparative Example 1, it can be concluded that the resist underlayer films formed from the resist underlayer film-forming compositions of Examples 1 to 5 had favorable flatness.

### INDUSTRIAL APPLICABILITY

In the present invention, it is possible to provide a composition for forming a resist underlayer film that does not cause mixing when photoresist compositions or different resist underlayer films are laminated and has an improved ability to fill patterns during baking by improving heat-reflowability of the polymer.

1. A resist underlayer film-forming composition comprising a compound of the following Formula (A) and/or Formula (B), and a solvent: 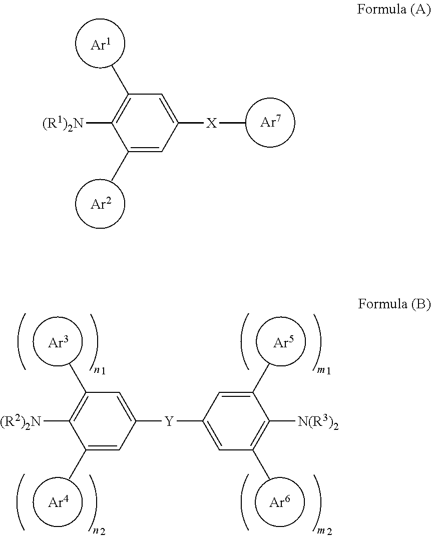
(in Formula (A), Ar¹ and Ar² are each independently a group consisting of one or more aromatic rings having a carbon atom number of 6 to 30 that is substitutable with Z¹, R¹ is a hydrogen atom, a C₁₋₁₀ alkyl group, a C₂₋₁₀ alkenyl group or a C₂₋₁₀ alkynyl group, X is a single bond or an oxygen atom, Ar⁷ is the same group as Ar¹ and Ar² when X is a single bond, and is a phenyl group or a naphthyl group when X is an oxygen atom,
in Formula (B), Ar³ to Ar⁶ have the same definition as Ar¹ and Ar², R² and R³ each have the same definition as R¹, Y is a single bond or a divalent group that is substitutable with Z², n1, n2, m1, and m2 are 0 or 1, and n1, n2, m1, m2 are not all 0 at the same time,
Z¹ is at least one selected from the group consisting of a halogen atom, a hydroxy group, a cyano group, a methylamino group, a methyl ether group, a cyclic alkyl group, a benzene group, a pyridine group, a C₁₋₁₀ alkyl group, a C₂₋₁₀ alkenyl group and a C₂₋₁₀ alkynyl group, and
Z² is at least one selected from the group consisting of a C₁₋₁₀ alkyl group and a C₁₋₁₀ fluoroalkyl group).

2. The resist underlayer film-forming composition according to claim 1, wherein, in Formula (A) or Formula (B), Ar¹ to Ar⁶ are each independently a group consisting of one or more aromatic rings including a benzene ring.

3. The resist underlayer film-forming composition according to claim 1, wherein, in Formula (A), R¹ is a hydrogen atom or a C₂₋₁₀ alkynyl group.

4. The resist underlayer film-forming composition according to claim 1, wherein, in Formula (B), Ar³ to Ar⁶ are the same group.

5. The resist underlayer film-forming composition according to claim 1, wherein, in Formula (B), the divalent group is a group selected from the group consisting of a branched or linear alkylene group having a carbon atom number of 1 to 15, a phenylene group, a naphthalene group, an anthracenyl group, a sulfonyl group, a carbonyl group, an ether group, and a thioether group or a group of combinations thereof.

6. The resist underlayer film-forming composition according to claim 5, wherein, in Formula (B), the divalent group is any of groups shown below: 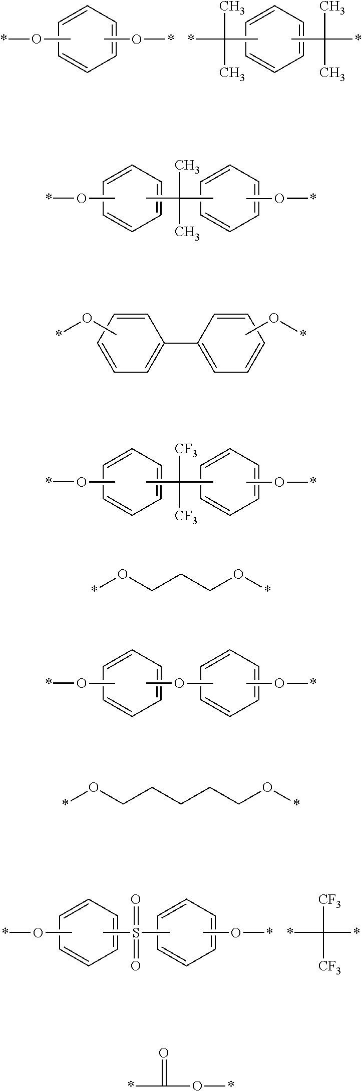
(* is a bond to an aromatic ring)

7. The resist underlayer film-forming composition according to claim 1, wherein, in Formula (B), R² and/or R³ are a hydrogen atom or a C₂₋₁₀ alkynyl group.

8. The resist underlayer film-forming composition according to claim 1, further comprising a crosslinking agent.

9. The resist underlayer film-forming composition according to claim 1, further comprising an acid and/or an acid generating agent.

10. The resist underlayer film-forming composition according to claim 1, wherein the solvent is a solvent having a boiling point of 160° C. or higher.

11. A resist underlayer film which is a baked product of a coating film formed from the resist underlayer film-forming composition according to claim 1.

12. A method for producing a semiconductor device, the method comprising:
a step of forming a resist underlayer film on a semiconductor substrate using the resist underlayer film-forming composition according to claim 1;
a step of forming a resist film on the resist underlayer film;
a step of forming a resist pattern by emitting light or an electron beam and development;
a step of etching the resist underlayer film with the resist pattern; and
a step of processing the semiconductor substrate with the resist underlayer film that is patterned.
